(19) United States
(12) Patent Application Publication
(10) Pub. No.: US 2026/0324135 A1
(43) Pub. Date: Oct. 15, 2026

(54) MICRO- AND NANO-SCALE LIGHT EMITTING DEVICES

(71) Applicant: The Regents of the University of Michigan, Ann Arbor, MI (US)

(72) Inventor: Zetian MI, Ann Arbor, MI (US)

(21) Appl. No.: 19/572,482

(22) Filed: Mar. 19, 2026

Related U.S. Application Data
(60) Provisional application No. 63/775,994, filed on Mar. 21, 2025.

(51) Int. Cl. H10H 20/812; H10H 20/01; H10H 20/813; H10H 20/816; H10H 20/818; H10H 20/825

(52) U.S. Cl. CPC H10H 20/812; H10H 20/0137; H10H 20/8132; H10H 20/816; H10H 20/818; H10H 20/825

(57) ABSTRACT

In various embodiments, the present technology includes a light emitting device including one or more sub-micron dimension nanowires. It is noted that each nanowire can include: an indium gallium nitride active region including a nitrogen polarity (N-polar) along a growth axis and semipolar along the facets; magnesium-doped aluminum gallium nitride electron-blocking layer disposed on the indium gallium nitride active region; and p-type doped gallium nitride layer having a p-type gradient doping profile increasing away from the active region.

### CROSS-REFERENCE TO RELATED APPLICATION

This application claims the benefit of U.S. Provisional Patent Application No. 63/775,994 filed on Mar. 21, 2025 entitled “Micro- and Nano-Scale Light Emitting Devices,” by Zetian M I, Attorney Docket No. NSUM-0020-00.00US, which is hereby incorporated by reference.

### BACKGROUND OF THE INVENTION

In recent years, the display industry has been moving towards smaller scale optoelectronic devices due to their potential for achieving better resolution and higher efficiency at reduced cost. Organic light-emitting diodes (OLEDs) and inorganic III-V-based LEDs have been adopted in several applications where their liquid crystal display (LCD) precursors were unable to meet consumer needs, due to the bulkiness and relatively poor device efficiency. OLEDs suffer from an efficiency roll-off at higher operating powers, resulting in significantly lower output power than their inorganic counterparts. They are highly resistive, with usual device operation occurring at current densities in the mA/cm² range, which is several orders of magnitude below that of inorganic LEDs, leading to the comparatively low brightness and very low light output when scaled down to small sizes. OLEDs also suffer from other issues such as limited emitter lifetime and burn-in effects, particularly for higher energy blue wavelengths. Micro-scale inorganic light emitting devices can potentially address these problems as they combine the advantages of superior material properties of inorganic devices with the greater versatility of small-scale devices that operate at low currents. Furthermore, augmented and virtual reality require ultra-high resolutions, and micro-scale light emitting device have been widely considered as the most promising candidate to attain the required pixel size.

Micro-scale light emitting devices have attracted extensive research interests due to their emerging applications including displays, virtual/augmented reality and visible-light communication. Displays for future technologies such as augmented and virtual reality require ultra-high resolution and efficient power consumption. While micro-scale light emitting devices can attain the required sizes for these displays, at present their efficiencies are severely lacking, especially the red-emitting ones.

### BRIEF DESCRIPTION OF DRAWINGS

Embodiments of the present technology are illustrated by way of example and not by way of limitation, in the figures of the accompanying drawings and in which like reference numerals refer to similar elements and in which:

FIG. 1 shows a plot against area of the light emitting device active region for the variation of WPE of InGaN (red spheres) and organic (orange diamonds) based light emitting device.

FIG. 2(a) shows a schematic of a fabricated micro-light emitting device.

FIG. 2(b)shows the nanowire heterostructure.

FIG. 2(c) shows a photoluminescence spectrum of a representative array of nanowires having a red-emitting InGaN active region grown above an InGaN/GaN short-period superlattice (SPSL).

FIG. 2(d) shows a scanning transmission electron microscope high-angle annular dark field image of a representative nanowire.

FIG. 3(a) shows characterization of device performance including J-V characteristics of the submicron scale red light emitting device.

FIG. 3(b) shows variation of the device's measured light output power vs. current density.

FIG. 3(c) shows variations of EQE.

FIG. 3(d) shows variations of WPE vs. injection current density.

FIG. 4(a) shows EL spectra measured from the fabricated submicron-scale light emitting device at different injection currents.

FIG. 4(b) shows peak position.

FIG. 4(c) shows FWHM of the EL spectra at different currents.

FIG. 5(a) shows a schematic of the InGaN/GaN nanowire array arranged in a photonic crystal structure.

FIG. 5(b) shows a top view SEM image of the as-grown InGaN/GaN PhC structure with lattice constant a of 360 nm and diameter d of 220 nm.

FIG. 5(c) shows a cross-sectional STEM image of the active region of the InGaN/GaN heterostructure.

FIG. 5(d) shows a photoluminescence spectra measured from the as-grown sample after Al₂O₃ passivation and SiO₂ deposition.

FIG. 5(e) shows a Band structure of the nanowire photonic crystal structure.

FIG. 5(f) shows a power-dependent photo luminescence PL measurements of the structure with SiO₂ and Al₂O₃ passivation over an excitation range of over two orders of magnitude.

FIG. 6(a) shows aschematic of the InGaN/GaN micro-light emitting device structure.

FIG. 6(b) shows current-voltage characteristics of the devices.

FIG. 6(c) shows normalized EL spectra of the devices.

FIG. 6(d) shows current-dependent EL spectra for the micro-light emitting device.

FIG. 6(e) shows the optical microscope image of the red-emitting micro-light emitting device under different injection currents.

FIG. 7(a) shows the chromaticity coordinate of the red-emitting micro-light emitting device.

FIG. 7(b) shows the FWHM as a function of peak wavelength.

FIG. 8(a) shows the EQE as a function of current density.

FIG. 8(b) shows the far-field emission distribution of the micro-light emitting devices.

FIG. 8(c) shows the vertical emission mechanism wherein the light waves propagate in the forward and backward directions.

FIG. 8(d) shows the EQE measured as compared to the conventional art.

### DETAILED DESCRIPTION OF THE INVENTION

Reference will now be made in detail to the embodiments of the present technology, examples of which are illustrated in the accompanying drawings. While the present technology will be described in conjunction with these embodiments, it will be understood that they are not intended to limit the technology to these embodiments. On the contrary, the invention is intended to cover alternatives, modifications and equivalents, which may be included within the scope of the invention as defined by the appended claims. Furthermore, in the following detailed description of the present technology, numerous specific details are set forth in order to provide a thorough understanding of the present technology. However, it is understood that the present technology may be practiced without these specific details. In other instances, well-known methods, procedures, components, and circuits have not been described in detail as not to unnecessarily obscure aspects of the present technology.

Some embodiments of the present technology which follow are presented in terms of routines, modules, logic blocks, and other symbolic representations of operations on data within one or more electronic devices. The descriptions and representations are the means used by those skilled in the art to most effectively convey the substance of their work to others skilled in the art. A routine, module, logic block and/or the like, is herein, and generally, conceived to be a self-consistent sequence of processes or instructions leading to a desired result. The processes are those including physical manipulations of physical quantities. Usually, though not necessarily, these physical manipulations take the form of electric or magnetic signals capable of being stored, transferred, compared and otherwise manipulated in an electronic device. For reasons of convenience, and with reference to common usage, these signals are referred to as data, bits, values, elements, symbols, characters, terms, numbers, strings, and/or the like with reference to embodiments of the present technology.

It should be borne in mind, however, that these terms are to be interpreted as referencing physical manipulations and quantities and are merely convenient labels and are to be interpreted further in view of terms commonly used in the art. Unless specifically stated otherwise as apparent from the following discussion, it is understood that through discussions of the present technology, discussions utilizing the terms such as “receiving,” and/or the like, refer to the actions and processes of an electronic device such as an electronic computing device that manipulates and transforms data. The data is represented as physical (e.g., electronic) quantities within the electronic device's logic circuits, registers, memories and/or the like, and is transformed into other data similarly represented as physical quantities within the electronic device.

In this application, the use of the disjunctive is intended to include the conjunctive. The use of definite or indefinite articles is not intended to indicate cardinality. In particular, a reference to “the” object or “a” object is intended to denote also one of a possible plurality of such objects. The use of the terms “comprises,” “comprising,” “includes,” “including” and the like specify the presence of stated elements, but do not preclude the presence or addition of one or more other elements and or groups thereof. It is also to be understood that although the terms first, second, etc. may be used herein to describe various elements, such elements should not be limited by these terms. These terms are used herein to distinguish one element from another. For example, a first element could be termed a second element, and similarly a second element could be termed a first element, without departing from the scope of embodiments. It is also to be understood that when an element is referred to as being “coupled” to another element, it may be directly or indirectly connected to the other element, or an intervening element may be present. In contrast, when an element is referred to as being “directly connected” to another element, there are not intervening elements present. It is also to be understood that the term “and or” includes any and all combinations of one or more of the associated elements. It is also to be understood that the phraseology and terminology used herein is for the purpose of description and should not be regarded as limiting.

Aspects of the present technology are directed toward micro-scale light emitting devices. The light emitting devices employ a combination of nitrogen polarity (N-polarity), magnesium doped (Mg-doped), aluminum gallium nitrogen (AlGaN) electron blocking layer, and a p-doped gallium nitride (p-GaN) layer with a gradient doping profile to advantageously achieve enhanced carrier injection efficiencies. In embodiments of the present technology, a high wall-plug efficiency for a red light emitting sub-micron light emitting device has been achieved.

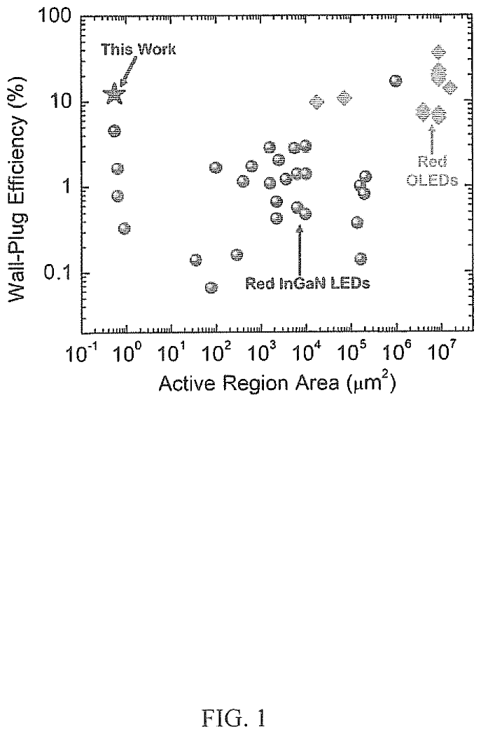

At present, the efficiency of micro-light emitting devices is severely lacking, inhibiting their use in practical applications. Referring to FIG. 1, the wall-plug efficiencies (WPEs) of III-nitride based and organic LEDs of different sizes are plotted together. Conventional top-down processing of micro-LEDs requires a plasma etch to define mesas for individual devices on a wafer. Previous studies have shown that this process creates a large density of surface defects on the device perimeter. Defects on the surface area of the sidewalls contribute to the nonradiative surface recombination of injected carriers, lowering the device efficiency significantly. The contribution of this non-radiative recombination increases drastically for micro-light emitting devices due to the higher ratio of surface area to volume, leading to abysmally low efficiencies for devices with lateral sizes of a few tens of microns and smaller. Also, in the case of III-nitride light emitting devices, the high lattice mismatch between the InGaN active region and typical GaN substrates makes it extremely difficult to attain a high indium composition without the generation of defects, which is a necessity for high efficiency long wavelength red emission. The large piezoelectric polarization fields generated from the lattice mismatch cause a further drop in the internal quantum efficiency of the emission due to the separation of the electron and hole wavefunctions. This spatial separation between the electrons and holes due to the polarization fields in the active region also results in a shift in the emission wavelength of the devices with varying injection current, known as the quantum-confined Stark effect (QCSE). Besides the QCSE, the large disparity between electron and hole mobilities, typical of the III-nitrides, leads to overflow of electrons outside the active region, further lowering the device efficiency. While AlGaN electron blocking layers (EBLs) have been commonly implemented in light emitting devices for mitigating the electron overflow, the large bandgap of these layers, combined with the large polarization fields generated in them, can obstruct the injection of holes into the active region.

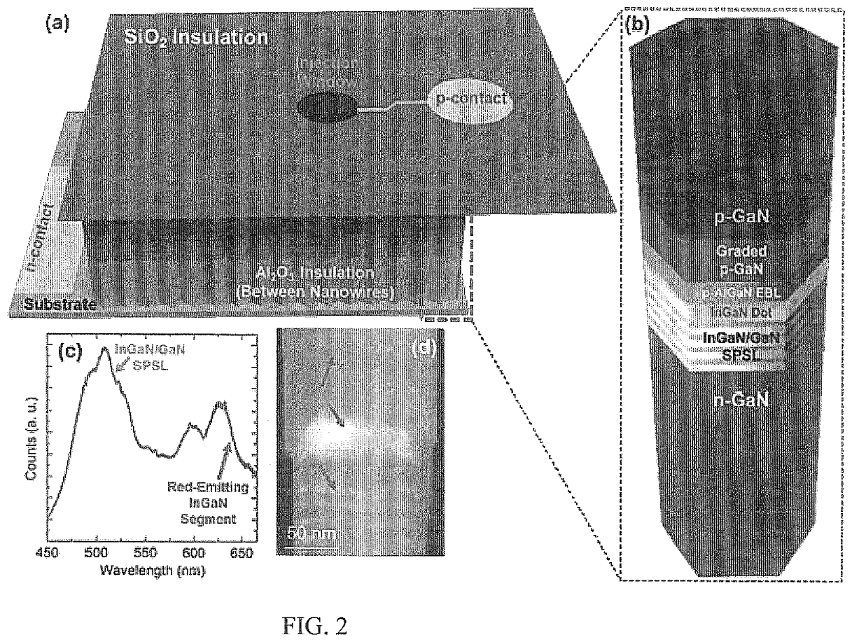

Challenges in achieving high device efficiency that traditional top-down Ga-polar InGaN micro-light emitting devices face have been overcome on a bottom-up, nitrogen polar (N-polar) nanowire platform. This bottom-up approach eliminates the need for a plasma etch step through the device stack during device fabrication, thereby protecting the active region from the deleterious surface recombination commonly seen in conventional top-down micro-light emitting devices. In addition, nanowires form a strain-relaxed and defect-free template that can greatly enhance their active region's quantum efficiency, which is crucial for high efficiency red emission. It has been shown that InGaN layers within these nanowires are formed along the growth axis and also on the semi-polar facets. The InGaN layers on the sidewall facets are strain-relaxed and have significantly reduced polarization fields, greatly increasing the exciton binding energy. The large exciton binding energy leads to high efficiencies of such devices in low injection regimes, where highly efficient excitonic radiative recombination dominates. To reduce electron overflow/leakage and achieve high wall-plug efficiency with these N-polar red-emitting nanowires, an AlGaN electron blocking layer (EBL) can be incorporated, as well as a p-GaN layer with graded Mg-doping. In addition to reducing the electron overflow, the AlGaN EBL helps to minimize the diffusion of Mg into the active region as well. Previous work has also shown that AlGaN layers in III-nitride nanostructure devices can form a core-shell structure that protects the active region from surface recombination. The N-polarity of the nanowires also generates polarization fields within the EBL that can enhance hole injection into the active region, in contrast to the AlGaN EBL in conventional metal-polar devices, where the polarization fields of the EBL impede hole injection. To ensure good structural morphology and reduced Mg atom diffusion into the InGaN layers, the Mg doping in the p-GaN layer was graded initially, with the doping increasing away from the active region. Referring now to FIG. 2(a), a fabricated submicron-scale light emitting devices is schematically shown. The fabricated submicron-scale light emitting device exhibited a peak wavelength of approximately 650 nanometers (nm) and reached a maximum external quantum efficiency (EQE) of approximately 12.8% and a wall-plug efficiency (WPE) of approximately 12.2%. The electrical efficiency for the device peaks at approximately 95%, which is comparable to large area red micro-light emitting devices.

The bottom-up approach begins with selective area epitaxy (SAE), which was carried out in a Veeco GEN930 plasma-assisted molecular beam epitaxy (PA-MBE) system to grow the N-polar III-nitride nanowires. For the preparation of the SAE substrate, a 10 nm thick titanium Ti mask layer was deposited on a silicon doped (Si-doped) N-polar GaN-on-sapphire template, into which openings were defined through electron beam lithography. After etching through the Ti mask layer in the openings, the substrates can be cleaned and then loaded into the MBE system for the nanowire growth. Referring now to FIG. 2(b), a schematic of the nanowire heterostructure is shown. Initially, a 500 nm thick Si-doped n-GaN segment was grown, followed by the growth of an InGaN/GaN short-period superlattice (SPSL). The SPSL was capped with an approximately 20 nm thick undoped GaN spacer layer, following which a red-emitting InGaN segment active region was grown and capped with approximately 50 nm of undoped GaN. A similarly grown structure exhibits the formation of a faceted InGaN segment, where the strain-relaxed semi-polar facets have higher indium composition than the central axial region of the nanowire. Electrical measurements on fabricated devices suggested that at low current injections, radiative carrier recombination occurred mostly within these faceted regions. Referring now to FIG. 2(c), a representative photoluminescence (PL) spectrum is plotted showing the luminescence peaks from both the SPSL at approximately 510 nm and the InGaN dot at approximately 630 nm. Following the growth of the active region, a lightly Mg-doped AlGaN electron blocking layer (EBL) was grown at a substrate temperature of approximately 1030 °C, with a thickness of approximately 25 nm and using an initial Mg beam equivalent pressure (BEP) of approximately 2×10⁻⁹ Torr that was ramped to approximately 1×10⁻⁸ Torr by the end of the layer. The Al composition of the EBL is uniform and estimated to be approximately 5-10%. Referring now to FIG. 2(d), the AlGaN EBL is approximately 20 nm in thickness along the c-axis and also forms a thin shell on the non-polar sidewall planes. Subsequently, the p-GaN segment with graded Mg-doping was grown over approximately 20 nm, with the Mg acceptor flux increasing from approximately 1×10⁻⁸ Torr to 5×10⁻⁸ Torr. An approximately 150 nm thick p-GaN segment was then grown with the final higher Mg flux. As high Mg incorporation can result in the formation of crystalline defects that degrade nanowire morphology, the gradient doping was implemented to avoid directly using the high Mg flux throughout the p-GaN layer. Further, higher Mg incorporation also promotes lateral growth in nanowires, which can potentially create parallel diode paths that bypass the active region, especially if the lateral growth extends to the bottom n-GaN layer. The graded Mg doping scheme minimizes this lateral growth, resulting in excellent nanowire morphology and device performance.

Following the device growth, the fabrication process for submicron scale light emitting devices continues with an initial deposition of aluminum oxide Al₂O₃ using atomic layer deposition (ALD). ALD allows the insulating dielectric to fill the gap in between the nanowires, thus preventing a direct metal connection between the n-type and p-type regions. The Al₂O₃ on top of the nanowires is then etched back using reactive ion etching (RIE) until the top p-GaN is exposed. Plasma-enhanced chemical vapor deposition was used to deposit an approximately 500 nm thick silicon dioxide SiO₂ layer into which the actual micro-light emitting device openings having an area of 750 nm×750 nm were etched using stepper lithography and RIE. This etch step was performed iteratively so as to minimize the over etch of the top p-GaN layer, while ensuring that all the insulating dielectric layers are etched away from the nanowire surface. Over-etch of the p-GaN can affect the contact resistance due to plasma damage, while leftover insulation layers would present a large barrier to hole injection. Metallization to form the n and p contacts and their subsequent annealing ensued. Finally, a reflective metal stack was deposited over the devices to increase the reflection of device emission towards the backside sapphire for device power measurements.

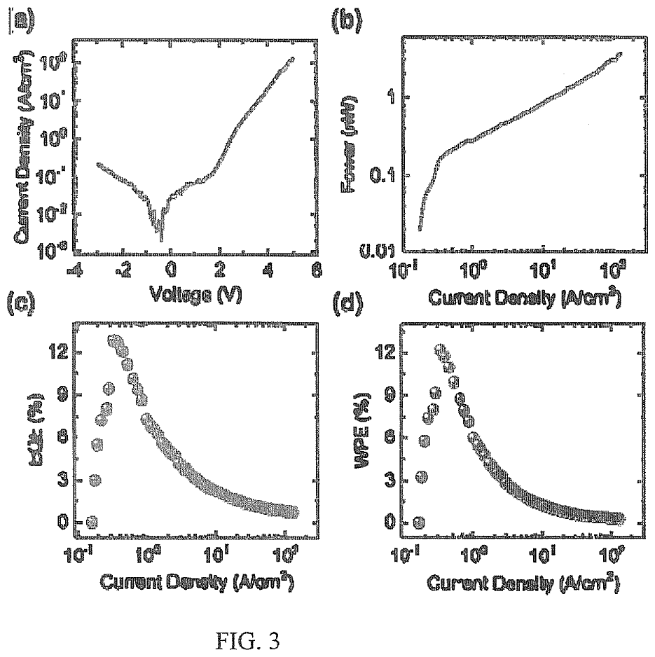

Referring now to FIG. 3(a), the current-voltage characteristics of a fabricated device are shown. The device exhibits low leakage current, indicative of a well-formed p-n junction, while also showing an excellent turn-on voltage of approximately 2 V. Typically, higher turn-on voltages are seen in light emitting devices when barriers are formed at the metal contacts or in high resistivity cladding layers, and their absence here confirms the excellent electrical properties of the device and optimized fabrication process. The output power from the device was collected from the bottom of the sapphire substrate and measured on-wafer using a calibrated Newport 1818-R power meter connected to a Newport 918D-UV-ST detector. Referring to FIG. 3(b), the L-J characteristics are plotted, which show a sharp increase in emission power up to a current density of approximately 1.2-1.4 A/cm², following which the increase is more gradual, indicating a change in the recombination mechanism. Referring now to FIG. 3(c) and 3(d), the EQE and WPE were calculated from the L-J and J-V data and plotted, respectively. A peak EQE of 12.8% was measured at a current density of approximately 1.22 A/cm², while the maximum WPE was approximately 12.2% at approximately 1.22A/cm² . As such, the device's electrical efficiency is approximately 95%, despite the presence of an AlGaN EBL. It should also be noted that the device exhibits a pronounced droop in efficiency at injection currents over a few A/cm². This droop could be a consequence of excitonic disassociation within the faceted regions of the nanowire. To shift this efficiency droop to higher injection currents, exciton disassociation could be mitigated, either by reducing the density of carriers within the faceted regions of the nanowires, or by increasing the exciton binding energy. Engineering of the nanowire shape, the strain state of the InGaN layer, and the composition of the InGaN can affect the geometry of the nanowire faceting, thereby allowing for control of the physical recombination volume of carriers. Apart from that, increasing the exciton binding energy through strain engineering, ultra-thin InGaN layers, or the use of different crystal orientations for growth could shift the efficiency peak to higher injection currents.

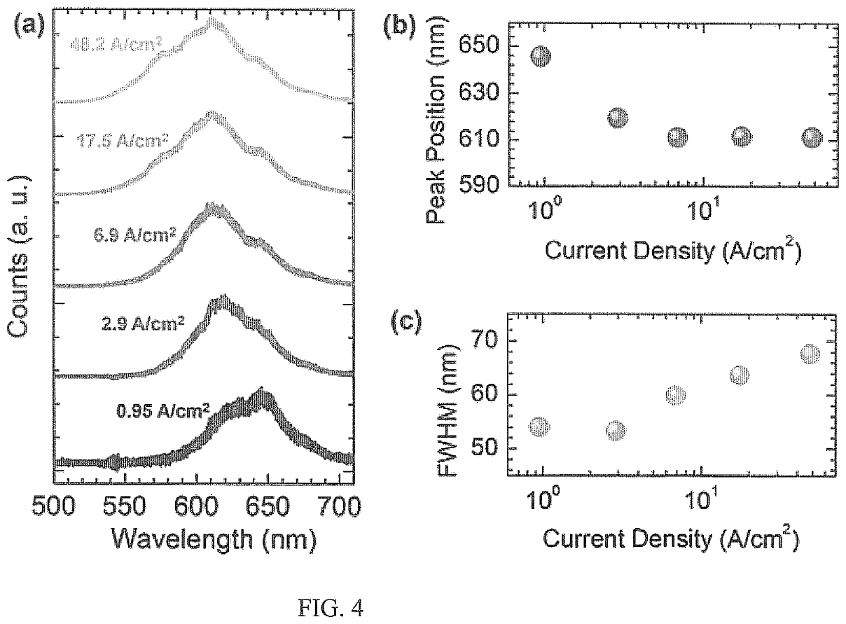

The electroluminescence (EL) spectra of the device were measured at different operating current densities and plotted in FIG. 4(a). At low current densities, close to and below the maximum efficiency point, the peak emission wavelength is noticeably longer at approximately 650 nm. With increasing current injection levels, the peak at approximately 650 nm remains, however the shorter emission at approximate 615 nm begins to dominate. The shift in the emission wavelength corresponds closely to the peaks in both EQE and WPE, while also being near the point of a marked shift in the slope of the L-J curve. It should be noted that the spectra also present strong Fabry-Perot modes. Referring now to FIG. 4(b), plots of the peak position of the EL spectra at the different injection currents are shown. The full-width half-maximum (FWHM) of the peak is plotted in FIG. 4(c). The initial decrease and subsequent increase in the FWHM have previously been seen in InGaN, where they are attributed to the screening of the polarization fields and the effect of band-filling, respectively. All these factors together indicate a pronounced shift in the nature of recombination near this operating current density. The contribution of emission from the SPSL is not expected to play a role as their emission is at even shorter wavelengths, from which no emission is seen. However, studies have shown that InGaN segments in nanowires form a faceted morphology, where higher indium composition regions are found on the non-polar facets at the nanowire sidewalls. The interplay of carrier injection and recombination within these different composition layers, grown on different crystal planes with different polarization fields, likely results in the device characteristics presented, where at low injection levels, carriers are more likely to form excitons and recombine radiatively in the high indium composition regions along the sidewalls, corresponding to the longer wavelength emission that rapidly increases with injection current. The shift towards recombination in the bulk of the nanowire occurs at higher injection likely due to saturation of available statesin the faceted regions of the nanowires. The high carrier density also leads to the disassociation of the excitons. The shift in carrier concentrations from the faceted region to the bulk of the nanowire results in a larger contribution from the less efficient radiative recombination in the bulk. This recombination produces the shorter wavelength emission, corresponding to the more gradual increase in emission power with respect to injection current density shown in the L-J characteristics.

Advantageously, in accordance with an exemplary implementation of the present technology, and efficient InGaN-based submicron-scale red micro-light emitting devices with an EQE of approximately 12.8% and WPE of approximately 12.2%, and having a peak emission wavelength approximately 650 nm can be achieved. The high on-wafer efficiencies for a sub-micron scale light emitting device can be attained with the effective minimization of non-radiative recombination using bottom-up nanowires and the high-quality red-emitting InGaN active region. The distinctive InGaN active region formed within the nanowires creates narrow InGaN layers on the semipolar facets, increasing exciton binding energies. The excitonic recombination of carriers at low injection currents facilitated by this nanostructure is responsible for the high quantum efficiency of carrier recombination. The WPE, which approaches the EQE in value, shows that the device has near unity electrical efficiency. Detrimental changes to the nanowire morphology associated with high Mg doping levels were avoided through the use of gradient doping in the p-doped layers. Accordingly, nanowires in accordance with aspects of the present technology can be used as the basis for micro-light emitting device technology, being able to attain a WPE of over 10% for a red light emitting device having a lateral size under 1 μm.

InGaN-based micro-light-emitting diodes (micro-light emitting devices) are also emerging to revolutionize the display and lighting technologies, particularly for their excellent chemical robustness, high brightness, high efficiency, and small pixel size. The excellent chemical robustness, wide bandgap tunability and relatively low surface recombination velocity of InGaN, are the potential advantages for realizing blue, green and red micro-light emitting devices in one material system, which is highly desirable for monolithic integration and large-scale manufacturing of micro-light emitting device displays. Remarkable progress has been achieved in alleviating the efficiency deterioration during the scaling down of micro-light emitting devices by using techniques such as low-damage etching and surface passivation, particularly in the blue and green-emitting micro-light emitting devices. Recently, while the external quantum efficiency (EQE) of blue and green InGaN micro-light emitting device has reached over 20% and 10%, respectively, the EQE of micrometer-scale red InGaN micro-light emitting device is below several percent EQE values, which can be mainly attributed to the high densities of defects and dislocations in high indium composition InGaN quantum wells.

In addition to the EQE, the color purity is another major parameter to be optimized for displays, but has not yet received sufficient attention among the investigations conducted in InGaN micro-light emitting devices. Micro-light emitting devices with high color purity hold great potential for transforming traditional displays due to their ability to achieve high contrast ratio, wide color gamut, and excellent color saturation. In general, high-color-rendering capabilities demands light sources with a full-width-at-half-maximum (FWHM) of less than 10 nm for all three primary colors as well as high color stability under various injection currents. However, compositional segregation and larger built-in electric field in high indium composition InGaN quantum well (QW) causes significant blue-shift in emission color with injection current and broad emission with typical FWHM of 40-90 nm. Moreover, there exists significant blue-shifts with injection current due to the screening of quantum-confined Stark effect (QCSE). Both prevent the realization of high-quality displays with appealing color rendering.

Despite the success of blue light emitting devices, long-wavelength emission, particularly the red emission, has been a challenge for InGaN-based micro-light emitting devices. Overcoming the low quantum efficiency, color instability and broad emission in the red wavelength regime are among the most urgent and critical problems that inhibit the commercial implementation of micro-light emitting device technology.

Accordingly, other aspects of the present technology are directed toward micro-scale light emitting devices that employ a nanowire photonic crystal (PhC) structure to reform radiation behavior of indium gallium nitride (InGaN) devices. Through detailed optimization on the PhC design and device fabrication, red-emitting micro-light emitting devices with peak wavelength at 617 nm and full width half maximum of 5 nm, which is about one order of magnitude narrower than previous reported values, can be achieved. The chromaticity property is highly stable with varying injection currents due to the coupling of emissions to photonic band edge mode. A record high external quantum efficiency of over 10% was measured from micro-light emitting devices with size of 1 μm². Accordingly, aspects of the present technology provide for high optical performance red-emitting micro-light emitting devices and potential pathway for full-color micro-light emitting device technology by using all group III-nitride semiconductors.

The nanowire photonic crystal (PhC) structure can be used to significantly improve the performance of InGaN red-emitting micro-light emitting devices. The spontaneous emission characteristics of the micro-light emitting device are manipulated by coupling the emission of the InGaN/GaN active region to the photonic band edge mode of the PhC. Pure red emission with narrow linewidths and negligible shift in emission color can be obtained over a large range of injection currents. Through control of the PhC design and device fabrication, record high EQE values can be achieved from a micrometer scale InGaN micro-light emitting device.

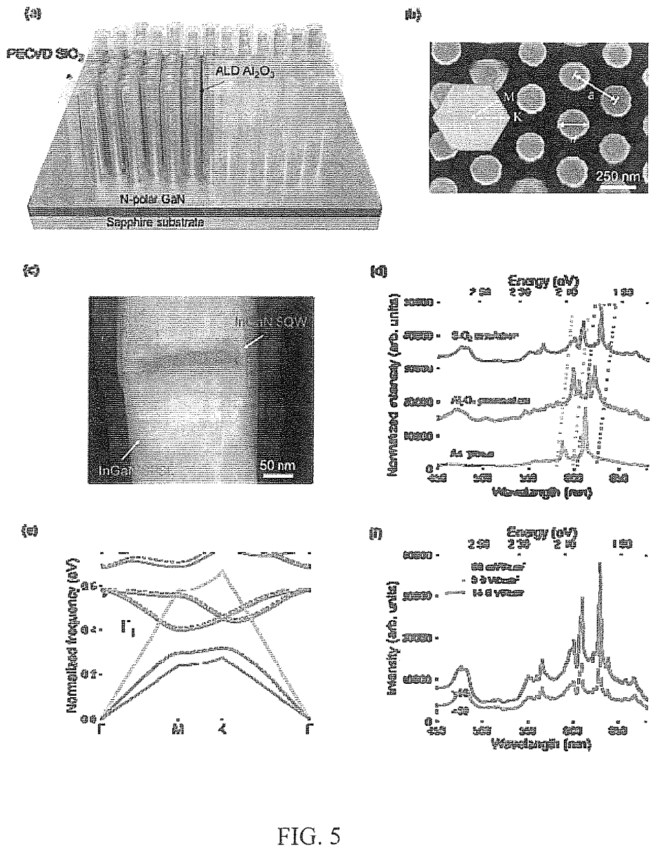

Referring now to FIG. 5(a), the schematic of the nanowire PhC structure with Al₂O₃ surface passivation deposited by atomic layer deposition (ALD) and SiO₂ insulation deposited by plasma-enhanced chemical vapor deposition (PECVD). The epitaxy of the InGaN/GaN heterostructure was performed on a nitrogen polar GaN on sapphire substrate with 10 nm patterned Ti mask. Prior to the growth of the red-emitting InGaN single quantum well (SQW), four periods of n-type doped InGaN/GaN short period superlattices (SPSL) were grown to effectively release the strain and enhance the indium incorporation in the subsequent InGaN SQW growth. A top view scanning electron microscope (SEM) image of the as-grown nanowire array with the lattice constant a and diameter d labelled is shown in FIG. 5(b). FIG. 5(c) illustrates the cross-sectional scanning transmission electron microscope (STEM) image of the active region of the InGaN/GaN heterostructure, wherein the red false-colored region depicts the InGaN SQW and the green false-colored region depicts the SPSL. The selective area growth of the bottom-up nanowire array and the related substrate patterning process is described below. FIG. 5(d) compares the normalized photoluminescence spectra of a nanowire PhC with a of 360 nm and d of 220 nm under different passivation conditions. Multiple sharp emission lines were observed from the as-grown nanowire PhC array. The dominant mode is at 612 nm with FWHM of approximately 3 nm, which corresponds to the photonic band edge mode (┌1) as indicated in the calculated photonic bandstructure in FIG. 5(e). The peaks at 587 nm and 591 nm can be attributed to different photonic band edge modes.

After the surface passivation of 10 nm Al₂O₃, two peaks around 616 nm and 623 nm were observed while the shorter wavelength peaks shifted to 599 nm and 604 nm, respectively, along with the alternations in the relative peak intensities. The dashed red lines in FIG. 5(e) are the photonic bandstructure of Al₂O₃ passivated PhC structure, wherein the normalized frequency at ┌1 point shifts up by approximately 0.15, which agrees with the red shift of approximately 10 nm in the peak positions. ALD-based surface passivation has been widely used for reducing the leakage current through the etching induced damage on the sidewalls in micro-light emitting devices. Al₂O₃ passivation with a thickness of 5 nm, 10 nm, 20 nm and 60 nm have been adopted in the samples with nominally the same PhC design and growth conditions and no optical resonance was observed using 20 nm and 60 nm Al₂O₃ passivation. The thickness of the sidewall passivation layer greatly affects the geometry and the distribution of refractive index of the photonic crystal structure, wherein thicker passivation reduces the refractive index contrast between InGaN/GaN nanowire and the gaps as well as PhC effect. The red curve in FIG. 5(c) is the PL spectrum of the nanowire PhC measured after additional 300 nm SiO₂ deposition, wherein the SiO2 functions as the insulation layer during the metallization of electrodes. The dominant peak further shifts to 629 nm while other peaks are located at 600 nm and 609 nm. The evolution of the peaks with different passivation or insulation conditions are indicated by the dashed boxes in FIG. 5(c). Red-shifts with similar trends have been consistently observed from patterns with different designs.

Referring now to FIG. 5(f), the power-dependent PL measurements performed on the nanowire PhC structure after Al₂O₃ and SiO₂ deposition, is shown. In the power-dependent PL measurements, the emission peak is invariant with the excitation power varied over 2 orders of magnitude, which is in direct contrast to the significant blue-shift of 20-50 nm observed in conventional red InGaN light emitting devices due to the screening of the quantum-confined Stark effect (QCSE). The excited carriers within the InGaN SQW generate spontaneous emission coupled to the photonic band edge mode of the PhC structure, wherein the emission wavelength is insensitive to the carrier density, and negligible emission wavelength is obtained.

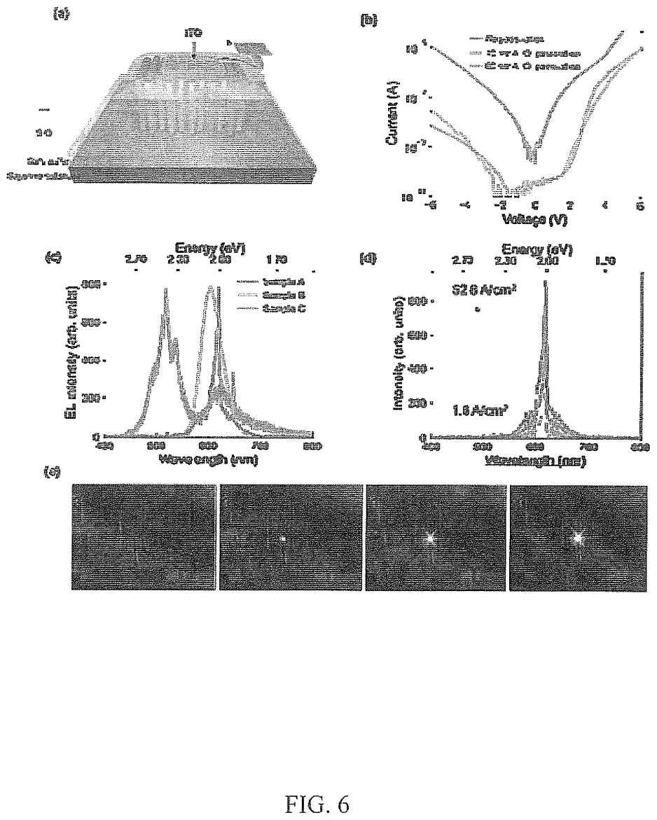

Following the deposition of the SiO₂ layer, photolithography followed by fluorine-based reactive ion etching (RIE) can be performed to define the injection windows with sizes ranging from sub-micrometer scale to 8 μm×8 μm. The metallization includes ITO for the p-contact and Ti/Au for the n-contact. Referring now to FIG. 6(a), a schematic of the as-fabricated nanowire PhC micro-light emitting device is shown. Three samples of InGaN/GaN nanowire PhC were grown under nominally identical conditions and fabricated using the same processing, except with Al₂O₃ thickness of 10 nm (Sample A), 60 nm (Sample B) and without Al₂O₃ passivation (Sample C). Detailed fabrication parameters are set forth below. Referring now to FIG. 6(b) the current-voltage (I-V) characteristics of micro-light emitting devices with size of 1 μm² from the three samples are compared, wherein the measured device in Sample A has a of 320 nm and d of 240 nm, and the devices in Sample B and C have a of 360 nm and d of 220 nm. Current densities of Sample A and B are similar and are one to two orders of magnitude lower than that of Sample C. ALD thin-films with thicknesses ranging from 7-30 nm can be adopted for sidewall passivation in micro-light emitting devices. Meanwhile, the rectification ratio of Sample A and B at ±6 V is two orders of magnitude higher than that without passivation (Sample C). The reduction in current density at both forward and reverse bias with ALD thin-film passivation has been observed before and was attributed to reduction in sidewall surface state and less trap states for charge carriers. Referring now to FIG. 6(c), the normalized electroluminescence (EL) spectra of the three samples, wherein the emissions from the InGaN/GaN short superlattice is absent and only the emissions from the red-emitting InGaN SQW present for Sample A and Sample B, is shown. The FWHM of Sample B is approximately 50 nm, which is comparable to the 45-80 nm linewidth reported from other InGaN red-emitting light emitting devices. EL spectrum of Sample A contrasts that of Sample B in that a sharp peak at 617 nm is superimposed with the red-emitting background. The sharp peak has a FWHM of approximately 5 nm, which is about one order of magnitude narrower than that of the previous reports. Red-emitting sharp line at 645 nm is observed from Sample C as well. However, a broad emission with peak at 512 nm was observed from Sample C, which can be attributed to the emissions from the InGaN/GaN short superlattice. Considering that the high current density and poor rectification ratio measured from Sample C, the emission from the superlattice can be attributed to the leakage current from the sidewall.

Current dependent EL measurements were performed on Sample A and it can be seen from FIG. 6(d) that the peak wavelength is nearly invariant when the injection current increases by over one order of magnitude. The excellent color stability was further confirmed by the optical images of a 5 μm×5 μm red-emitting micro-light emitting device under injection current densities from 0.36 A/cm² to 7.8 A/cm² as shown in FIG. 6(e), wherein no variations in emission color was observed. Moreover, red rays radiating from the micro-light emitting device were seen to propagate along the six equivalent ┌-K directions in the surrounding PhC region. The observation of propagating light is possibly due to some surface roughness between the SiO₂ insulation layer and the nanowire top. Such radiation pattern is absent in Sample B where the gaps between the InGaN nanowires are fully filled by the Al₂O₃.

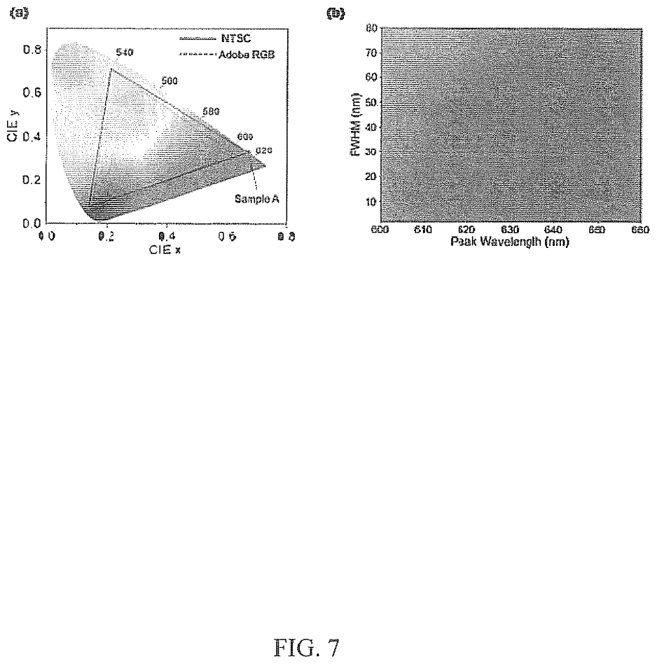

The chromaticity coordinate of the red-emitting micro-light emitting device in Sample A is (0.67, 0.33), which is marked as a red star in the International Commission on Illumination (CIE) 1931 chromaticity diagram as shown in FIG. 7(a). This coordinate coincides with that of the primary red color in the widely used National Television Standards Committee (NTSC) standard and is beyond the color gamut area of the Adobe RGB. In previously reported InGaN red-emitting micro-light emitting devices, while excellent color purity can be achieved at low current densities of a few A/cm², the chromaticity coordinates deviates from the red region and the color gamut coverage reduces due to the significant blueshift with injection current. In the presented micro-light emitting device based on InGaN nanowire PhC, the chromaticity coordinate remains almost constant when the micro-light emitting devices were driven at different current densities due to the negligible shift in peak wavelength. The effect of the spectral linewidth on the chromaticity of red-emitting micro-light emitting devices is illustrated by plotting the chromaticity of the luminescence spectra with Gaussian distribution in the wavelength range of 600-660 nm and FWHM range of 2-80 nm. As shown in FIG. 7(b), the FWHM plays a significant role in deviating the color from red to amber when the peak wavelength is below 630 nm. Namely, emission peak wavelengths of over 630 nm are desirable for achieving pure red emission at typically observed FWHM of approximately 70 nm from InGaN micro-light emitting devices. It's worth noting that although the FWHM broadening has a limited influence on the color purity when peak wavelength is above 640 nm, or over 50% indium composition, such high indium composition could lead to high densities of defects and dislocations in the InGaN/GaN quantum wells and greatly deteriorate the EQE.

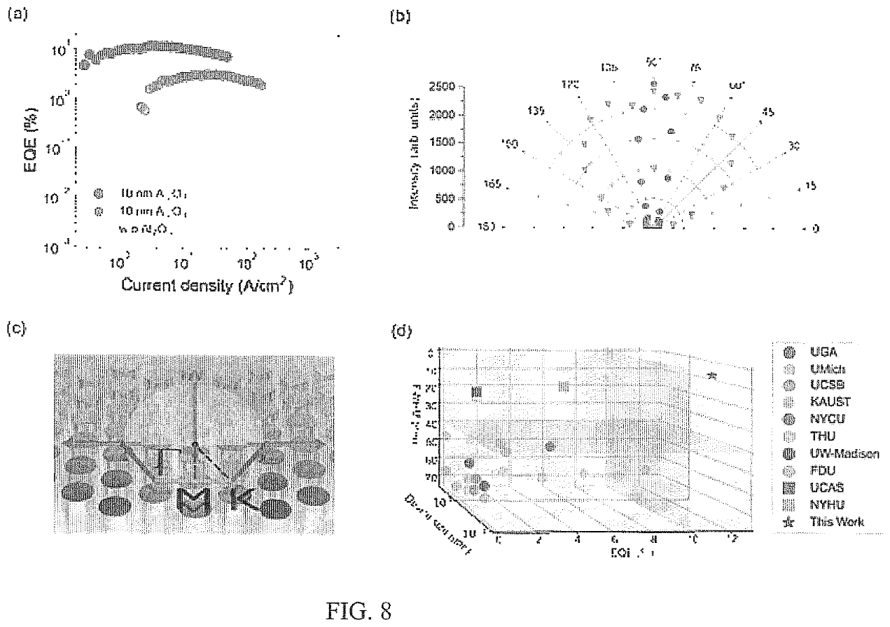

The devices in Samples A, B and C were further fabricated by depositing metal reflectors consisting of 150 nm Al/10 nm Ti/20 nm Au on top of the ITO for EQE measurements, wherein the samples were placed on top of a silicon detector for optical power measurements without any packaging. As shown in FIG. 8(a), a peak EQE of 12% was measured from the device of Sample A, which is about four times that of the device in Sample B and is about two orders of magnitude larger than that of the device in Sample C. Angular-resolved EL measurements were performed to investigate the far-field emission distribution of the micro-light emitting devices in Sample A and Sample B and the results are shown in FIG. 8(b). The EL emission from the device in Sample A is mainly distributed along the direction that is perpendicular to the device surface, within a divergence angle of less than 15°. In contrast, the EL collected from Sample B follows a distribution that is close to a Lambertian distribution. The vertical emission mechanism is illustrated in FIG. 8(c) wherein the light waves that propagate in the forward and backward directions along the ┌-K directions couples together and their wave vectors satisfying the first order Brag condition, resulting in redistribution of photonic energy in the vertical direction. The much smaller emission divergence angle benefits efficient light reflection at the top metal reflector in Sample A, which results in higher light extraction efficiency. The EQE of Sample A peaks at current density of 4 A/cm², which is about two to three orders of magnitude lower than that of Sample C. Previous reports have shown that leakage current causes a low EQE and higher peak EQE current density, which is further confirmed by the lack of apparent droop in the EQE as observed from Sample C. FIG. 8(d) marks the EQE measured as compared to the conventional art. This shows the highest EQE values and smallest linewidth for red-emitting InGaN micro-light emitting devices.

In accordance with embodiments of the present technology, by coupling the spontaneous emission of InGaN/GaN heterostructure to the photonic band edge mode of a nanowire PhC structure, pure red emission with narrow emission linewidth of 5 nm can be achieved and no variations in emission color was observed over a wide variation of injection current. The chromaticity coordinate of the red micro-light emitting device reaches the primary red color in the NTSC standard, which indicates excellent color-rendering potential over a large color gamut area. Directional emissions primarily along the vertical direction of the nanowire PhC structure were measured, which effectively improved the light extraction efficiency and a record high EQE of 12% was obtained from micrometer scale red micro-light emitting devices. The excellent optical performance of the InGaN red micro-light emitting devices paves the way for monolithic integration of GaN-based RGB-pixelated micro-light emitting devices with CMOS-based driver circuitry.

In an exemplary implementation, the epitaxial growth of the InGaN was performed on N-polar GaN on a sapphire substrate. Prior to growth, the substrate was first coated with 10 nm Ti film, which was subsequently patterned by e-beam lithography, and an etching process to create triangular lattice of GaN holes. After standard solvent cleaning, the patterned wafer was loaded into the MBE system for outgassing and subsequent nanowire micro-light emitting devices growth. The growth starts with the n-GaN segment at 680 °C, Gallium beam equivalent pressure (BEP) of approximately 3×10⁻⁷ Torr, and nitrogen flow of 0.5 sccm. Prior to the growth of the red-emitting InGaN active region, four periods of Si-doped InGaN/GaN SPSL were grown to effectively release the strain and enhance the indium incorporation in the subsequent InGaN SQW growth. The active region was grown at a substrate temperature of 570 °C, Gallium BEP of approximately 6×10⁻⁸ Torr, and In BEP of approximately 1×10⁻⁷ Torr. The nitrogen flow rate was 0.7 sccm for enhanced indium incorporation during active region growth. The p-GaN was grown at 680 °C for 60 mins. Mg BEP of 2×10⁻⁸ Torr was used.

The fabrication continues with ALD of Al₂O₃ for sidewall passivation, followed by a fluorine-based reactive ion etching (RIE) process to reveal the top of the p-GaN. Then 300 nm SiO₂ was deposited by PECVD as the insulation layer, followed by lithography and another RIE etching to open the current injection window for each submicrometer/micrometer scale light emitting device. The p-metal contact consists of 180 nm ITO deposited via a sputtering process, which provides excellent coverage on the sidewall of the SiO₂ insulation layer. Chlorine-based RIE process on n-GaN was performed followed by deposition of 20 nm Ti/80 nm Au for n-metal contact. Annealed in N₂ ambient was performed at 500 °C for 1 min. Sample B and C were processed using similar processes except that Al₂O₃ of 60 nm was deposited on Sample C to completely fill the air gaps and no Al₂O₃ passivation was deposited on Sample B. The top metal reflector consisting of 150 nm Al/10 nm Ti/20 nm Au was deposited by e-beam evaporator.

The current-voltage (I-V) characteristics of the as-fabricated micro-light emitting devices were measured using a Keithley 2400 voltage source meter. PL characterizations were performed by 405 nm laser excitation. The emissions from the nanowire array were collected by an optical fiber placed on top of sample to collect the emission in a direction perpendicular to the PhC surface. The EL spectra were also collected by an optical fiber. The emissions were spectrally resolved by high-resolution spectrometers equipped with liquid nitrogen/thermal electrically cooled CCD cameras. The angle-dependent EL spectra were collected using a fiber mounted on a rotation stage.

The foregoing descriptions of specific embodiments of the present technology have been presented for purposes of illustration and description. They are not intended to be exhaustive or to limit the present technology to the precise forms disclosed, and obviously many modifications and variations are possible in light of the above teaching. The embodiments were chosen and described in order to best explain the principles of the present technology and its practical application, to thereby enable others skilled in the art to best utilize the present technology and various embodiments with various modifications as are suited to the particular use contemplated. It is intended that the scope of the invention be defined by the claims appended hereto and their equivalents.

1. A light emitting device including one or more sub-micron dimension nanowires, each nanowire comprising:
an indium gallium nitride active region including a nitrogen polarity (N-polar) along a growth axis and semipolar along the facets;
magnesium-doped aluminum gallium nitride electron-blocking layer disposed on the indium gallium nitride active region; and
p-type doped gallium nitride layer having a p-type gradient doping profile increasing away from the active region.

2. The light emitting device including the one or more sub-micron dimension nanowires of claim 1, wherein each nanowire further comprising:
a short-period superlattice region including a plurality of indium gallium nitride layers interposed with a plurality of gallium nitride layers, wherein the indium gallium nitride region is disposed on the short-period superlattice region.

3. The light emitting device including the one or more sub-micron dimension nanowires of claim 2, wherein each nanowire further comprising:
a nitrogen polar, n-type doped, group-III semiconductor-nitride layer, wherein the short-period superlattice region is disposed on nitrogen polar, n-type doped, group-III semiconductor-nitride layer; and
a p-type gallium nitride layer disposed on the p-type doped gallium nitride layer.

4. The light emitting device including the one or more sub-micron dimension nanowires of claim 1, comprising a peak wavelength of approximately 650 nanometer, a maximum external quantum efficiency of approximately 12.8%, a wall-plug efficiency of approximately 12.2%, and an electrical efficiency for the device peaks at approximately 95%.

5. A method of manufacturing a light emitting device comprising:
selective area epitaxy of a nitrogen polar, n-type doped, group III-nitride semiconductor layer;
selective area epitaxy of an indium gallium nitride active region on the nitrogen polar, n-type doped, group III-nitride semiconductor layer, wherein the indium gallium nitride active region includes a nitrogen polarity along a growth axis and semipolar along the facets;
selective area epitaxy of a magnesium-doped aluminum gallium nitride electron-blocking layer disposed on the indium gallium nitride active region; and
selective area epitaxy of a p-type doped gallium nitride layer disposed on the magnesium-doped aluminum gallium nitride electron-blocking layer, wherein the p-type doped gallium nitride layer has a p-type gradient doping profile increasing away from the active region.

6. The method of manufacturing the light emitting device of claim 5, further comprising:
selective area epitaxy of a short-period superlattice region including a plurality of indium gallium nitride layers interposed with a plurality of gallium nitride layers, wherein the short-period superlattice region is formed on the nitrogen polar, n-type doped, group III-nitride semiconductor layer before the indium gallium nitride active region is formed.

7. A light emitting device comprising:
a photonic crystal structure comprising an array of nanowires with a lattice constant a and diameter d geometry, each nanowire including:
a short-period superlattice region including group III-nitride semiconductor; and
an active region, including a group III-nitride semiconductor single quantum well, disposed on the short-period superlattice region.

8. The light emitting device of claim 7, wherein:
the group III-nitride semiconductor short-period superlattice region comprises an indium gallium nitride short-period superlattice region; and
the group III-nitride semiconductor single quantum well active region comprises an indium gallium nitride single quantum well active region.

9. The light emitting device of claim 7, further comprising nanowire sidewall passivation selected from a group consisting of aluminum oxide and silicon oxide.

10. The light emitting device of claim 7, wherein:
the lattice constant a of the array of nanowires is in the range of 320-360 nm; and
the lattice distance d of the array of nanowires is in the range of 220-240 nm.

11. The light emitting device of claim 7, wherein a spontaneous emission of the active region is coupled to a photon band edge move of the photonic crystal structure of the array of nanowires.
